(19) United States
(12) Patent Application Publication
(10) Pub. No.: US 2024/0061387 A1
(43) Pub. Date: Feb. 22, 2024

(54) Configuration of Electrical Devices Connected in Series

(71) Applicant: Pilz GmbH & Co. KG, Ostfildern (DE)

(72) Inventors: Markus Lenz, Ostfildern (DE); Martin Schnaithmann, Ostfildern (DE)

(21) Appl. No.: 18/450,867

(22) Filed: Aug. 16, 2023

(30) Foreign Application Priority Data
Aug. 16, 2022 (DE) 10 2022 120 665.3

(51) Int. Cl. G05B 15/02

(52) U.S. Cl. CPC G05B 15/02

(57) ABSTRACT

An apparatus includes multiple electrical devices, each configurable with respect to a control variable. The electrical devices each have an input that applies an input signal, an output that provides an output signal, and a measuring unit that determines a voltage applied to the respective electrical device. The electrical devices are arrangeable in a series circuit in which a first electrical device of the electrical devices is connectable to an input signal relevant to the series circuit and each further electrical device is respectively connected with its input to the output of a previous electrical device of the series circuit. Within each electrical device, the respective input is coupled to the associated output such that a defined voltage drop is established when a defined potential is applied to the respective input. The electrical devices each adjust a control variable relevant to the respective device based on the measured voltage.

### CROSS-REFERENCE TO RELATED APPLICATIONS

This application claims priority to German patent application 10 2022 120 665.3 filed 16 Aug. 2022, the entire disclosure of which is incorporated by reference.

### FIELD

The present disclosure relates to safety systems and more particularly to a safety apparatus using interlock switches.

### BACKGROUND

Series circuits of electrical devices are used for various applications, including in the field of automation technology, and have the advantage that wiring effort can generally be reduced compared to individual wiring of the electrical devices. Furthermore, series circuits are advantageous if the principle of a chain is to be established with the electrical devices, e.g. in the sense of a logical AND interconnection of the electrical devices.

In a series connection, the individual electrical devices each have at least one input at which a signal can be received and an output at which an output signal is provided in response to a signal applied to the input. Further, the electrical devices are connected such that an output of one device is connected to an input of a subsequent device to form a chain. A signal applied to the input of a first device of the chain is then transmitted from one device to the next device via the described connection of the inputs and outputs.

For various applications, it is desired to individually configure the respective devices of the series connection. For example, in some applications, the respective devices should know their relative or absolute position within the chain in order to be able to perform a respective activity. Such a configuration can be done manually in a simple way via dip switches on the respective devices. Alternatively, a configuration can be stored in a memory of the respective device. In addition to a manual configuration, an automatic configuration is also possible if the devices can communicate with each other.

Manual configuration has the advantage that it is easy to implement, but has to be performed manually each time a device is added or removed or positions are swapped. Known methods for automatic configuration, on the other hand, are more flexible, but also much more complex to implement.

### SUMMARY

Interlock switches, especially those having a guard lock function, are often used for monitoring and safeguarding dangerous areas of a machine installation. In some applications, it is desirable to connect a plurality of interlock switches in series, but with individual switching times in response to a common switching command.

In view of the above, it is an object to provide a method and a apparatus which allow an individual configuration of devices of a series connection in a simple manner.

It is another object to provide a method and an apparatus, which can be realized easily and at low cost.

It is yet another object to provide a method and an apparatus which allow to flexibly change delay time parameters for a switching action.

It is yet another object to provide a safety apparatus comprising a plurality of interlock switches which allow to flexibly change control parameters of devices in a series connection.

In accordance with one aspect of the disclosure there is provided a safety apparatus comprising a plurality of interlock switches each configurable with respect to a delay time parameter defining a delay time prior to a switching action in response to a switching command signal, wherein the interlock switches each comprise a respective input configured for receiving a respective input signal, a respective output configured for providing a respective output signal, and a respective measuring unit configured for determining a respective voltage supplied to the respective electrical device, wherein the interlock switches are arranged in a series circuit in which a first interlock switch of the plurality of interlock switches is supplied with a first input signal and each further interlock switch of the plurality of interlock switches is connected with its respective input to the respective output of a previous interlock switch in the series circuit, wherein, within each interlock switch, the respective input is coupled to the respective output in such a manner that a defined voltage drop is established between the respective input and the respective output when a defined potential is applied at the respective input, wherein the interlock switches each are configured to adjust the delay time parameter based on the respective voltage measured by the respective measuring unit, and wherein the respective voltage measured in each of the plurality of interlock switches differs from the respective voltage measured in another interlock switch as a result of the defined voltage drop in each interlock switch of the plurality of interlock switches.

According to a further aspect, there is provided an apparatus comprising a plurality of electrical devices each configurable with respect to a respective control variable, wherein the electrical devices each comprise a respective input configured for receiving a respective input signal, a respective output configured for providing a respective output signal, and a respective measuring unit configured for determining a respective voltage supplied to the respective electrical device, wherein the electrical devices are configured to be arranged in a series circuit in which a first electrical device of the plurality of electrical devices is supplied with a first input signal and each further electrical device of the plurality of electrical devices is connected with its respective input to the respective output of a previous electrical device in the series circuit, wherein, within each electrical device, the respective input is coupled to the respective output such that a defined voltage drop is established between the respective input and the respective output when a defined potential is applied at the respective input, and wherein the electrical devices each are configured to adjust a respective control variable relevant to the respective electrical device based on the respective voltage applied to the respective electrical device and measured by the respective measuring unit.

According to a further aspect, there is provided a method of adjusting a plurality of control variables in a plurality of electrical devices, comprising the steps of providing the plurality of electrical devices, with each electrical device from the plurality of electrical devices having a respective device input configured for receiving a respective input signal, a respective device output configured for providing a respective output signal, and a respective measuring unit configured for determining a voltage applied to the respective electrical device, wherein the respective device input of each of the electrical devices is coupled to the respective device output in such a manner that a defined voltage drop is established between the respective device input and the respective device output when a defined potential is applied to the respective device input; arranging the plurality of electrical devices in a series circuit such that a first electrical device of the plurality of electrical devices is capable of receiving a series circuit input signal and each further electrical device of the plurality of electrical devices is connected with its respective device input to the respective device output of a previous electrical device in the series circuit; supplying the series circuit input signal to the first electrical device; measuring, in each electrical device of the plurality of electrical devices, a respective voltage at the respective device input; and adjusting the plurality of control variables in each of the plurality of electrical devices based on the respective voltage measured, wherein the respective voltages measured in each of the plurality of electrical devices differ from one another as a result of the defined voltage drop in each electrical device of the plurality of electrical devices.

It is thus an idea of the present disclosure to adjust electrical devices of a series connection via a voltage measured at the respective devices. For this purpose, the respective devices are set up in such a way that a voltage drop occurs within the respective devices between the voltage applied at the respective input and the voltage at the respective output, such that a voltage cascade is created across the series circuit. Consequently, if a constant voltage is applied to the input of the first device of the series circuit, an input voltage reduced by the sum of the voltage drops of the previous devices is established at the respective device of the series circuit. If the voltage drops are set accordingly, the input voltage at the individual devices will therefore differ from the input voltages at each of the other devices. In other words, due to the voltage cascade, a different voltage is present at each device and the voltage is unique within the series circuit.

This uniqueness can be used to assign a unique value to the respective device based on the measured voltage. The respective device can thus be configured using a unique value. Advantageously, this value can be determined at any time without having to store it in a memory of the respective device.

In addition, configuration via the voltage cascade allows the value to dynamically adapt to a change in the series connection (addition, removal, swapping of individual devices), but always remains unique within the series connection. The adjustment can take place automatically without the need for manual intervention.

Further, since the configuration requires only a defined voltage drop across the respective devices and a simple voltage measurement unit, complicated input and output circuitry can be dispensed with. Within the respective devices, the input and the output may advantageously be connected substantially directly to each other with only one passive element in between, which causes the—particularly— constant voltage drop. The input/output circuitry can thus be simple and of small size, thereby positively reducing the overall size of the respective devices. A simple input/output circuit also has the advantage that it is more robust in terms of electromagnetic compatibility (EMC) than dedicated input circuits and output circuits in digital technology. The object mentioned above is thus completely achieved.

In a further refinement, the input signal may represent a control command for the series connection, depending on which the electrical devices execute an action, wherein the execution of the action is further dependent on the configured control variable. Thus, the input signal need not be an input signal specially prepared for the configuration, but may be a signal that is applied to the electrical devices under normal operation. In particular, the input signal may be a control signal, based on which alone or in combination with other signals the electrical devices execute a control function. Consequently, the basic structure of a series circuit does not have to be changed by using the new input/output circuit.

In a further refinement, the action may be a switching function against a potential common to the series circuit, the control variable being a time variable, in particular a delay time, based on which a switching time can be determined. Due to the uniqueness of the control variable within the series circuit, it can be ensured in this way that the switching function is executed with a respective time delay in each of the electrical devices.

In a further refinement, an electrical component, in particular a Schottky diode, may be arranged between the respective input and the associated output of the electrical devices, which causes the defined voltage drop between the respective input and the associated output. Since a voltage is dropped across each passive component when current flows through it, various components can be connected between the input and output to produce the desired voltage drop. However, it is possible to use a diode, especially a Schottky diode, for this purpose, since it advantageously provides a small and largely constant voltage drop under variable ambient conditions. This refinement thus contributes to a further simplification of the input/output circuit.

In a further refinement, passive components are exclusively arranged between the respective input and the associated output within the electrical devices. The use of only passive components has the advantage that the input/output circuit can be implemented very inexpensively. The substantially direct connection between the input and the output also has the advantage that a signal transmission from the input to the output takes place almost without delay, so that a fast response time can be ensured within the series circuit.

In a refinement, the input signal at the respective input may provide the applied defined potential. Consequently, the voltage required for the voltage drop and thus for the configuration can be provided directly by an input signal applied to the input. This has the advantage that no additional voltage has to be provided for the configuration.

In a further refinement, the electrical devices of the series circuit may each be connected to a reference potential common to the series circuit and the respective input may be connected to the reference potential via a first resistor. The reference potential may be realized by a connection to a common ground potential. Alternatively, a reference potential may also be transmitted like the input signal from one electrical device to another electrical device. In this case, the first resistor acts as a series resistor via which a current can be set/limited, which current defines the voltage drop in cooperation with an electrical component. This refinement thus further contributes to a simple realization of the voltage drop in the respective devices.

In a further refinement, the electrical devices of the series circuit may each be connected to a supply potential common to the series circuit and the respective input may be connected to the supply potential via a second resistor. In this case, the potential decoupled from the supply potential via this resistor is the defined potential which is present at the respective input when the input to the first electrical device is at high impedance, i.e., when no input signal is present at the input to the first electrical device. This refinement helps to ensure that the configuration is advantageously not solely dependent on the presence of an input signal. Rather, even in the case where no input signal is present, configuration may be performed according to the previously described method. In this way, further applications can be realized based on this configuration principle.

In a further refinement, the electrical devices may be, for example, interlock switches with guard locking. Interlock switches are often used in series circuits, and in various applications it is advantageous if the interlock switch knows its absolute or relative position within the series circuit. The simple input/output circuit outlined here makes it easy to implement the configuration required for this purpose.

It goes without saying that the features mentioned above and those to be explained below can be used not only in the combination indicated in each case, but also in other combinations or on their own, without departing from the scope of the present disclosure.

### BRIEF DESCRIPTION OF THE DRAWINGS

Example embodiments of the disclosure are shown in the drawing and are explained in more detail in the following description.

FIG. 1 shows a schematic diagram of a series circuit according to an example embodiment of the present disclosure.

FIG. 2 shows a schematic diagram of an electrical device having an input/output circuit according to an example embodiment of the present disclosure.

FIG. 3 shows a schematic diagram of a series connection of interlock switches according to an example embodiment of the present disclosure.

FIG. 4 shows a schematic representation of an electrical device according to FIG. 2 with a modified input/output circuit.

FIG. 5 shows a schematic representation of a series connection of interlock switches with modified input/output circuits.

FIG. 6 shows a schematic representation of a method according to an example embodiment of the present disclosure.

### DETAILED DESCRIPTION

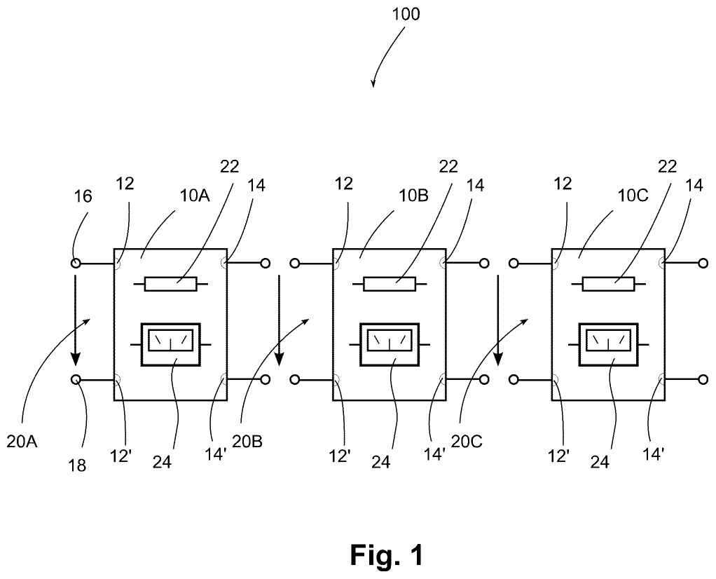

FIG. 1 shows a schematic diagram of a series circuit according to an example embodiment of the present disclosure. The series circuit is designated in its entirety here by reference numeral 100.

In this example, the series circuit is composed of three respective electrical devices 10A, 10B, and 10C. In the following description, reference number 10 is used when common elements are described for all electrical devices.

Electrical devices 10A, 10B, and 10C are connected in series to form series connection 100. Each device 10 has at least one input 12 and one output 14. The input 12 and the output 14 are coupled to each other so that a signal applied to the input (input signal) is transmitted to the output (output signal). As will be explained below, a direct connection of input and output is possible, but in principle not required for a series connection. It is also conceivable that the input is followed by an input circuit that receives the input signals, passes them on to a processing unit, which in turn drives an output circuit based on the evaluation of the input signals in order to provide the output signal.

An input signal may be applied to the input 12 of the first electrical device 10A by an external entity, such as a controller (not shown here). The input signal may be a static potential 16 defining, with respect to a reference potential 18, an input voltage 20A to the first electrical device 10A. The input signal is transmitted from the first electrical device 10A to the output 14. In various implementations, the input 12 is directly connected to the output 14 via a discrete electrical circuit, as will be further explained below with reference to the description of a single electrical device. The input signal transmitted to the output 14 of the first electrical device 10A forms the input signal of the next electrical device 10B in the series connection. The output 14 of the first electrical device 10A may, for example, be connected to the input 12 of the subsequent electrical device 10B via an electrical line. The input signal of the electrical device 10B is defined by an input voltage 20B with respect to the reference potential 18. The transmission of the input signal continues in the same way until the last electrical device, to which the input voltage 20C is finally applied.

In various example embodiments, reference potential 18 may also be carried through in the same manner, for example via further inputs and outputs 12′ and 14′ shown here. However, reference potential 18 may also be a common ground potential to which the individual electrical devices 10 are separately connected.

The input voltages 20A, 20B, and 20C at the electrical devices 10A, 10B, and 10C have a defined relationship to each other which, as shown below, is defined by the transmission of the input signal from input 12 to output 14 within the respective electrical devices 10. The transmission of the input signal from input 12 to output 14 is implemented such that a defined in various implementations, constant—voltage drop is established between the input 12 and the output 14.

For this purpose, an electrical component 22 may be connected between input 12 and output 14, which component causes the voltage drop AU. The electrical component 22 may be a passive component such as a diode, in particular a Schottky diode. In various implementations, the voltage drop is constant and the same in all electrical devices 10A, 10B and 10C. For example, the voltage drop may be 300 mV, which is low relative to an input voltage 20A of industry standard 24 V at the first electrical device.

Further, the respective electrical devices 10 include a measuring unit 24. The measuring unit 24 in each of the electrical devices is adapted to measure an instantaneous voltage applied to the electrical device. The measuring unit 24 may be arranged upstream of the electrical component 22. In various implementations, however, the measuring unit 24 is arranged downstream of the electrical component 22, i.e., on the output side. The voltage measured by the measuring unit 24 directly or indirectly determines a control variable of the respective electrical device. In one example embodiment, the measuring unit 24 may be an analog-to-digital converter (ADC) that assigns a defined digital value to any measured voltage value. The value determined by the analog-to-digital converter is then an example of the control variable.

Due to the series connection of the electrical components 22, a cascading voltage drop is established across the series connection. The voltage measured by the measuring unit 24 is consequently one step lower in each case than the voltage in the previous device. Due to the cascading, an individual voltage value results in each device of the series circuit, which individual voltage then determines the respective control variable. With suitable selection of the electrical components 22, it can be achieved that the individual voltage values in the individual electrical devices of the series circuit 100 are unique in each case. Consequently, the control variable can be used to assign a unique identifier within the series circuit to the respective electrical device. As will be explained below with reference to a specific example, this unique identifier can be used to execute a device-specific control function.

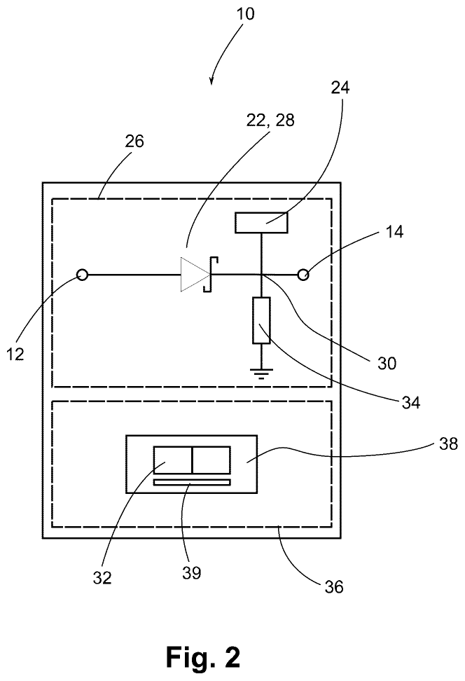

First, however, with reference to FIG. 2, an example embodiment of an input/output circuit 26 of a single electrical device 10 will be described in more detail. The input/output circuit 26 shown in FIG. 2 is an electrical circuit arranged between the input 12 and the output 14 of electrical device 10 adapted for use in a series circuit. The input 12 and the output 14 are substantially directly connected to each other with only one intervening passive component 22 in this example. The passive component 22 in this specific example is a Schottky diode 28. The Schottky diode 28 is forward connected between the input 12 and the output 14, and by design causes a low voltage drop AU between the input 12 and the output 14. The use of a Schottky diode 28 has the advantage that a low voltage drop can be easily set and remains largely constant under various external influences and environmental conditions. It is understood that the voltage drop can also be realized by another electrical component.

The input/output circuit 26 further includes a measurement point 30 in the connection between the input 12 and the output 14, to which the measurement unit 24 is coupled. Here, measuring unit 24 is an ADC of a microcontroller 32, which is not shown in further detail. In this example embodiment, measuring point 30 is arranged on the output side, i.e. between electrical component 22 and output 14. In another example embodiment, measuring point 30 may be arranged upstream of the diode, i.e. towards the side of the input 12.

A resistor 34 is also arranged in the input/output circuit 26 here. This resistor serves as a series resistor for the electrical component 22 (diode) and determines or limits the current through the electrical component 22 and consequently the resulting voltage drop.

Furthermore, electrical device 10 has a functional part 36 that performs the actual function of the electrical device 10. For example, functional portion 36 may include a processing unit 38 that performs a control function as depending on the input signal applied to the input 12. Moreover, processing unit 38 may be arranged to execute the control function in dependence on the control variable determined via measuring unit 24. In various implementations, the control function is thus implemented both depending on the input signal and depending on the determined control variable.

The processing unit 38 may, by way of example, be the microcontroller 32 which, among other things, also provides the ADC for the measuring unit 24. In addition, the processing unit 38 can also have a memory 39 in which the previously determined control variable can be stored. In various implementations, however, the control variable is determined repeatedly, so that no storage of the control variable is necessary.

It will be understood that the electrical devices 10 may have different functional parts 36 for different control functions, and only the input/output circuits 26 in these devices 10 are of identical design. Moreover, it is not necessary that each device 10 actually makes use of the control variable. Thus, devices 10 that rely on the control variable and other devices in the series connection can be used together.

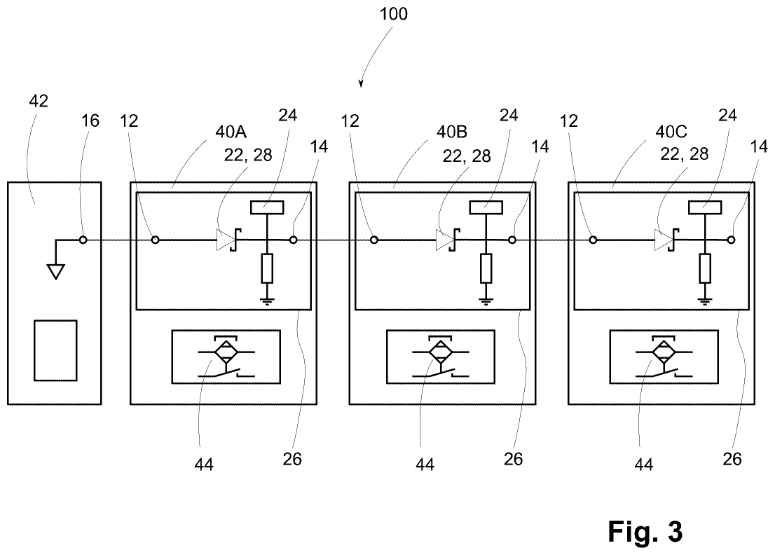

FIG. 3 shows a specific example of a series connection within the meaning of the present disclosure, in which interlock switches, as known from automation technology, are connected in series as electrical devices 10.

Interlock switches are used, for example, on machines and machine systems that exhibit hazardous movements or conditions and, according to applicable regulations, may not be operated without a protective device to prevent danger to persons working on them. For this purpose, a machine or machine system may be arranged in a fenced area or within an enclosure, for example. In order to be able to carry out maintenance work on the machine or machine system or in order to be able to insert or remove a workpiece despite the separating protective devices, a door or a cover or the like may be provided. It must be ensured that the door or cover cannot be opened during operation of the machine or machine system or, if this is attempted, that a forced shutdown is triggered. In addition, interlocking devices with guard locking are typically used for systems with dangerous, trailing movements. These keep the door or cover closed even after the machine has been switched off until the drives of the machine or machine system have come to a standstill. Only then can the door or cover be opened.

Interlock switches are often operated in a series circuit in technical systems in order to keep cabling effort as low as possible. As described above, the interlock switches function on the one hand as a sensor and, in the event that guard locking is required, simultaneously as an actuator that effects the guard locking. A linear solenoid is regularly used as an actuator in interlock switches, which can be switched by the interlock switch as a function of an input signal.

If several interlock switches with guard locking are arranged in a series circuit, it may happen that all actuators are switched simultaneously to control the respective solenoids. In this case, a high voltage drop can occur in the supply lines and result in the solenoids not switching or not switching reliably. In order to avoid such a scenario, delay elements may be arranged in the individual interlock switches in order to enable time-delayed switching in response to a common input signal. For this purpose, known interlock switches have, for example, a separate input circuit that is detached from the output circuit in the respective device. Furthermore, such switches have a processing unit that receives the input signal via the input circuit and controls the output circuit as a function thereof. Here it is possible to provide a delay element in the processing unit, which delays the forwarding of the input signal towards the output. The processing unit of the individual interlock switches can be configured manually or automatically and adapted to the respective series circuit so that time-delayed switching of the actuators can be achieved.

In the example embodiment shown in FIG. 3, three such interlock switches 40A, 40B and 40C are shown. Furthermore, FIG. 3 shows a control 42 that is set up to send an input signal to the interlock switches 40A, 40B and 40C connected in series. The controller 42, for example a safety controller, monitors the operation of a technical system and controls the interlock switches accordingly via the input signal. The input signal may be a binary signal that can assume an ON state or an OFF state. In the ON state, the input signal corresponds to a defined potential 16 which is present at the input 12 of the first interlock switch 40A. In the OFF state, no defined potential is present at the input 12, so that the input 12 of the interlock switch 40A is open or at high impedance. It is understood that an interlock switch may have further inputs and outputs or interfaces that may be relevant for realizing the desired function.

The input signal is transmitted from one interlock switch 40A, 40B to the next interlock switch 40B, 40C in the series circuit in the manner previously described. In this process, in each interlock switch 40A, 40B, 40C, the input voltage decreases by an amount defined by the electrical component 22. The measuring units 24 in the individual interlock switches 40A, 40B, 40C thus each measure a reduced voltage relative to the previous interlock switch 40A, 40B, 40C. An individual control variable for the interlock switches 40A, 40B, 40C can be generated from the measured voltage via a predefined assignment rule.

By way of example, the control variable may be a time variable that results, for example, from the following assignment rule:

tSwitch,ₙ=f(U)_{ADC,n}

tSwitch,ₙ is the control variable of the nth device, which results as a function of the voltage U_{ADC,n} measured at the nth device, for example in the form of a multiplication of the measured voltage U_{ADC,n} by a constant conversion factor. In particular, the control variable may represent a delay time that the interlock switch 40 waits after a change at the input 12 before the switch executes the corresponding control function. The control function may, for example, be the control of a magnetic switch 44, such as is indicated here in the functional part 36 of the interlock switch 40. Advantageously, the interlock switch 40 can thus derive the switching time directly from the measured voltage without the actuating variable actually having to be stored in the interlock switch.

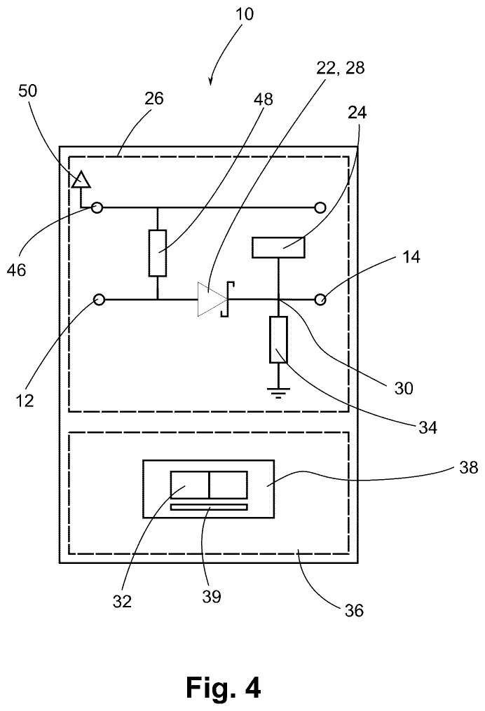

FIG. 4 shows another example embodiment of an electrical device with a further refinement of the input/output circuit 26.

In addition to the previously described elements of the input/output circuit 26 according to FIGS. 2 and 3, the input/output circuit 26 further comprises a terminal 46 for receiving a supply potential 50. Furthermore, the circuit comprises another resistor 48 arranged between the terminal 46 and the input 12. More specifically, the resistor 48 is arranged as a pull-up resistor and is connected on one side to the supply potential 50 and on the other side between the input 12 and the electrical component 22 causing the voltage drop. The resistor 48 may be, for example, a factor of 10 to 20 more highly resistive than the resistor 34.

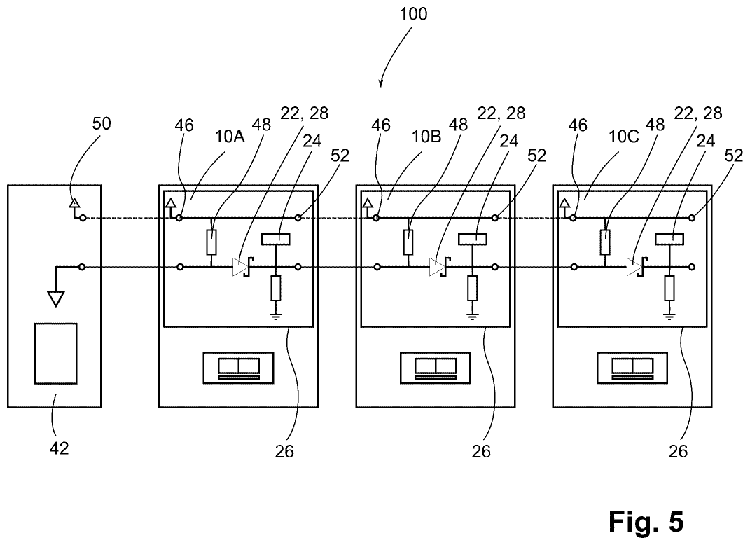

With the input/output circuit 26 according to FIG. 4, there is the advantage that even in the case that no input signal is applied to the input 12 and it is therefore highly resistive, a voltage divided by the pull-up resistor 48 and the series resistor 30 is applied to the electrical component 22. This voltage, reduced by the voltage drop across the electrical component 22, is made available at the output 14 and transmitted to the subsequent devices. Consequently, also when this input/output circuit 26 is used, a voltage cascade is formed across the series circuit, based on which the individual devices can be set in the manner described previously. An example of a corresponding series circuit is shown in FIG. 5.

FIG. 5 shows a series circuit 100 having three electrical devices 10A, 10B and 10C connected in series, each having an input/output circuit 26 according to the example embodiment shown in FIG. 4. The electrical devices 10A, 10B and 10C may, for example, again be interlock switches as described above.

The series-connected electrical devices 10A, 10B, and 10C each are connected to a supply potential 50 provided by controller 42 at terminal 46. In an example embodiment, the supply potential may be looped through from one device to the other device. For this purpose, in addition to the connection 46 via which they receive the supply potential 50, the devices may have a further connection 52 via which they provide the supply potential 50.

As shown in FIG. 5, a voltage is also provided for the case in which no input signal is present at the input 12 of the first electrical device 10A and this is open, so that a voltage cascade is also formed here via the series circuit, which cascade is caused by the respective voltage drops at the electrical components 22. Thus, it is also possible in this case to determine individual and unique voltage values for the respective electrical devices 10A, 10B and 10C via measuring units 24, based on which voltage values a control variable can be determined. This refinement thus makes it possible to configure a unique control variable in the electrical devices 10A, 10B and 10C even if no input voltage is present at the input 12 of the first device of the series circuit.

According to this example embodiment, a configuration of the individual electrical devices 10A, 10B and 10C can thus be performed regardless of the presence of an input signal at input 12 of the first electrical device. In this way, further applications can be realized.

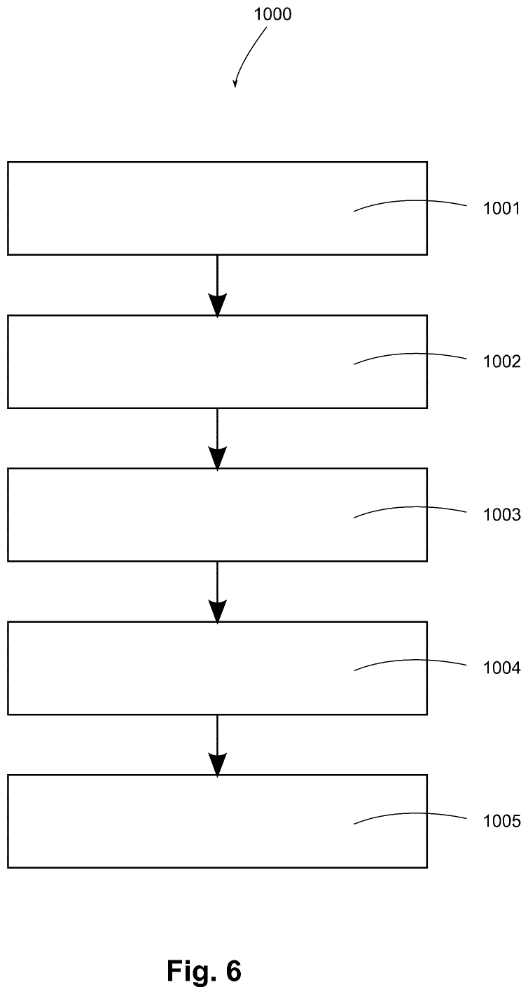

FIG. 6 shows in a schematic illustration a method according to an example embodiment of the present disclosure. The method is designated by reference numeral 1000 in its entirety.

In a first step 1001 of the method, electrical devices 10 are provided. The electrical devices 10 each have an input 12 for applying an input signal, an output 14 for providing an output signal, and a measuring unit 24 for determining a voltage applied to the respective electrical device 10.

In subsequent step 1002, the electrical devices 10 are combined to form a series circuit 100 by arranging the devices 10 one after the other in a chain. Here, the first device is connectable to an input signal and each further electrical device is connected in each case with its input to the output of the respective previous electrical device of the series connection.

In step 1003, a defined potential is applied to the input of the first electrical device of the series circuit, which potential is transmitted from the first device to the further electrical devices. During transmission, each of the electrical devices decreases the defined potential by a certain amount (defined voltage drop) so that a voltage cascade is established across the series circuit.

In step 1004, each electrical device measures a voltage currently applied to the respective electrical device via the associated measuring unit.

Finally, in step 1005, each electrical device configures a respective control variable relevant to the device based on the previously measured voltage.

It is understood that the method may comprise further steps or be performed in a modified manner. For example, at step 1001, the step of providing may include reconfiguration of an existing series circuit. In a reconfiguration, individual devices may be removed or added. Further, a reconfiguration may include swapping individual electrical devices in the series circuit. Also, for a reconfiguration at step 1001, the subsequent steps may performed in the same manner to reconfigure the electrical devices.

It is further contemplated that steps 1004 and 1005 are performed continuously so that the electrical devices automatically reconfigure as soon as the measured voltage changes based on the voltage cascade. This example embodiment is also advantageous when using a series circuit, such as that shown in FIG. 5, in which the voltage cascade adjusts sometimes based on the supply voltage and sometimes based on an input signal. In other words, reconfiguration may occur even when there is no input signal and the input to the first electrical device is open. In this case, the supply voltage takes the place of the input signal via the additional resistor.

For the sake of completeness, it should be mentioned that instead of automatic configuration, it is also possible to perform a configuration only at a specific time interval or in a specific time window. In this case, steps 1004 and 1005 may only be executed during this time interval or, if necessary, triggered manually during commissioning. In this case, it is advantageous if the configured control variable can be stored in a memory of the electrical devices. The manual configuration can be advantageous for a series connection of the electrical devices shown in FIG. 2 and FIG. 3.

It is understood that the above-mentioned example embodiments are generally to be understood as examples only, without limiting the subject matter of the present disclosure to that effect. Rather, the subject matter is defined and limited exclusively by the following claims.

1. A safety apparatus comprising:
a plurality of interlock switches, wherein:
each of the interlock switches is configurable with respect to a delay time parameter defining a delay time prior to a switching action in response to a switching command signal,
each of the interlock switches includes a respective input configured for receiving a respective input signal, a respective output configured for providing a respective output signal, and a respective measuring unit configured for determining a respective voltage supplied to the respective interlock switch,
the interlock switches are arranged in a series circuit in which a first interlock switch of the plurality of interlock switches is supplied with a first input signal and each further interlock switch of the interlock switches is connected with its respective input to the respective output of a previous interlock switch in the series circuit,
within each interlock switch, the respective input is coupled to the respective output in such a manner that a defined voltage drop is established between the respective input and the respective output when a defined potential is applied at the respective input,
each of the interlock switches is configured to adjust the delay time parameter based on the respective voltage measured by the respective measuring unit, and
the respective voltage measured in each of the plurality of interlock switches differs from the respective voltage measured in another interlock switch as a result of the defined voltage drop in each interlock switch of the plurality of interlock switches.

2. The safety apparatus of claim 1 wherein:
each of the plurality of interlock switches includes an electrical component arranged between the respective input and the respective output, and
the electrical component causes the defined voltage drop between the respective input and the respective output.

3. The safety apparatus of claim 2 wherein the electrical component is a Schottky diode.

4. An apparatus comprising:
a plurality of electrical devices, wherein:
each of the electrical devices is configurable with respect to a respective control variable,
each of the electrical devices includes:
a respective input configured to receive a respective input signal,
a respective output configured to provide a respective output signal, and
a respective measuring unit configured to determine a respective voltage supplied to the respective electrical device,
the electrical devices are configured to be arranged in a series circuit in which a first electrical device of the plurality of electrical devices is supplied with a first input signal and each further electrical device of the plurality of electrical devices is connected with its respective input to the respective output of a previous electrical device in the series circuit,
within each electrical device, the respective input is coupled to the respective output such that a defined voltage drop is established between the respective input and the respective output when a defined potential is applied at the respective input, and
each of the electrical devices is configured to adjust a respective control variable relevant to the respective electrical device based on the respective voltage applied to the respective electrical device and measured by the respective measuring unit.

5. The apparatus of claim 4 wherein:
the first input signal represents a control command for the plurality of electrical devices,
the plurality of electrical devices each perform a respective action in response to the control command, and
the respective action is further dependent on the respectively adjusted control variable.

6. The apparatus of claim 5 wherein the respective action is a switching action against a reference potential common to the plurality of electrical devices in the series circuit.

7. The apparatus of claim 5 wherein the respective control variable is a time variable defining an individual delay time before the respective action is performed in response to the control command.

8. The apparatus of claim 4 wherein:
the plurality of electrical devices each comprise an electrical component arranged between the respective input and the respective output, and
the electrical component causes the defined voltage drop between the respective input and the respective output.

9. The apparatus of claim 8 wherein the electrical component is a Schottky diode.

10. The apparatus of claim 4 wherein only passive electrical components are arranged between the respective input and the respective output of the plurality of electrical devices.

11. The apparatus of claim 4 wherein the respective input signal provides the defined potential.

12. The apparatus of claim 4 wherein:
the electrical devices of the series circuit each are connected to a reference potential common to the plurality of electrical devices, and
the respective inputs are connected to the reference potential via a respective first resistor.

13. The apparatus of claim 4 wherein:
the electrical devices each are connected to a supply potential common to the plurality of electrical devices, and
the respective inputs are connected to the supply potential via a respective second resistor.

14. The apparatus of claim 13 wherein the supply potential provides the defined potential applied to the respective input when the respective input of the first electrical device is at high impedance.

15. The apparatus of claim 4 wherein the electrical devices are interlock switches with guard locking.

16. An electrical device configured for use in a series circuit of a plurality of electrical devices, the electrical device comprising:
a device input configured to receive an input signal;
a device output configured to provide an output signal; and
a measuring unit configured to determine a voltage applied to the electrical device,
wherein the device input is coupled to the device output such that a defined voltage drop is established between the device input and the device output when a defined potential is applied to the device input, and
wherein the electrical device is configured to adjust a control variable relevant to the electrical device based on the voltage determined by the measuring unit.

17. A method of adjusting a plurality of control variables in a plurality of electrical devices, the method comprising:
providing the plurality of electrical devices, with each electrical device from the plurality of electrical devices having a respective device input configured for receiving a respective input signal, a respective device output configured for providing a respective output signal, and a respective measuring unit configured for determining a voltage applied to the respective electrical device, wherein the respective device input of each of the electrical devices is coupled to the respective device output in such a manner that a defined voltage drop is established between the respective device input and the respective device output when a defined potential is applied to the respective device input;
arranging the plurality of electrical devices in a series circuit such that a first electrical device of the plurality of electrical devices is capable of receiving a series circuit input signal and each further electrical device of the plurality of electrical devices is connected with its respective device input to the respective device output of a previous electrical device in the series circuit;
supplying the series circuit input signal to the first electrical device;
measuring, in each electrical device of the plurality of electrical devices, a respective voltage at the respective device input; and
adjusting the plurality of control variables in each of the plurality of electrical devices based on the respective voltage measured,
wherein the respective voltages measured in each of the plurality of electrical devices differ from one another as a result of the defined voltage drop in each electrical device of the plurality of electrical devices.
